(19) United States
(12) Patent Application Publication
(10) Pub. No.: US 2016/0190040 A1
(43) Pub. Date: Jun. 30, 2016

(54) WIRING LAYER FORMING METHOD, WIRING LAYER FORMING SYSTEM AND RECORDING MEDIUM

(71) Applicant: Tokyo Electron Limited, Tokyo (JP)

(72) Inventors: Mitsuaki Iwashita, Nirasaki City (JP); Takashi Tanaka, Nirasaki City (JP)

(21) Appl. No.: 14/972,623

(22) Filed: Dec. 17, 2015

(30) Foreign Application Priority Data
Dec. 25, 2014 (JP) 2014-263452

(51) Int. Cl. H01L 23/48; H01L 23/532; H01L 21/768

(52) U.S. Cl. CPC H01L 23/481; H01L 21/76898; H01L 21/76852; H01L 21/76874; H01L 21/76879; H01L 23/53238

(57) ABSTRACT

A seed layer and a barrier layer located outside a wiring layer on a surface of a substrate are easily removed by an etching process. A metal layer 25 composed of the barrier layer 23 and the seed layer 24 is formed on a surface of the substrate 2 and on an inner surface of a recess 2a, and then, a resist pattern is formed on the metal layer. The wiring layer 27 is formed within the recess 2a by supplying a plating liquid from an opening 26a of the resist pattern 26, and then, the metal layer 25 on the surface of the substrate 2 is removed by the etching process. The metal layer 25 is formed by an electroless plating process.

### CROSS-REFERENCE TO RELATED APPLICATION

This application claims the benefit of Japanese Patent Application No. 2014-263452 filed on Dec. 25, 2014, the entire disclosures of which are incorporated herein by reference.

### TECHNICAL FIELD

The embodiments described herein pertain generally to a wiring layer forming method and a wiring layer forming system for forming a wiring layer on a substrate, and a recording medium therefor.

### BACKGROUND

Recently, semiconductor devices such as a LSI or the like have been required to have higher density in order to meet requirements for reducing the mounting space or for improving the processing rate. As an example of a technology that achieves the higher density, there has been known a multilayer wiring technology of manufacturing a multilayer substrate, such as a three-dimensional LSI or the like, by stacking multiple wiring substrates.

According to the multilayer wiring technology, a through-via-hole, which penetrates a wiring substrate and in which a conductive material such as copper (Cu) is buried, is typically formed in the wiring substrate in order to obtain electrical connection between the wiring substrates. As an example of a technology for forming the through-via-hole in which a conductive material is buried, there has been known an electroless plating method.

As a specific method of producing a wiring substrate, there is known a method in which a substrate having a recess is prepared; a barrier layer as a Cu diffusion barrier film is formed on the substrate; and a seed layer is formed on the barrier layer. Thereafter, Cu is buried on the seed layer within the recess by electrolytic Cu plating, and the buried Cu constitutes a wiring layer within the recess.

As stated above, the barrier layer and the seed layer are formed on the substrate before the wiring layer is formed by burying the Cu within the recess of the substrate. The barrier layer and the seed layer are formed by a film forming process such as PVD (Physical Vapor Deposition) or CVD (Chemical Vapor Deposition). Accordingly, the barrier layer and the seed layer formed on a surface of the substrate have large thicknesses (equal to or larger than, e.g., 1000 nm in total). Thus, after forming the wiring layer by burying the Cu within the recess of the substrate, it is difficult to remove the seed layer and the barrier layer located outside the wiring layer on the surface of the substrate by etching or the like. Furthermore, when removing the barrier layer and the seed layer having the large thicknesses by the etching, it takes a long etching time, and the wiring layer may be also etched during this etching process.

Patent Document 1: Japanese Patent Laid-open Publication No. 2012-231096

### SUMMARY

In view of the foregoing, exemplary embodiments provide a wiring layer forming method and a wiring layer forming system capable of removing a seed layer and a barrier layer located outside a wiring layer on a surface of a substrate after forming the wiring layer within a recess of the substrate, and a recording medium therefor.

In one exemplary embodiment, a wiring layer forming method of forming a wiring layer on a substrate includes preparing the substrate having a recess; forming, on a surface of the substrate and on an inner surface of the recess, a metal layer composed of a barrier layer and a seed layer; forming, on the metal layer, a resist pattern having an opening which surrounds the recess; forming a wiring layer within the recess by a plating process in which a plating liquid is supplied from the opening of the resist pattern; and removing the metal layer, among the metal layer on the substrate, located outside the wiring layer by an etching process. Here, the seed layer of the metal layer is formed by an electroless plating process.

In another exemplary embodiment, a wiring layer forming system of forming a wiring layer on a substrate includes a metal layer forming unit configured to form, on a surface of the substrate having a recess and on an inner surface of the recess, a metal layer composed of a barrier layer and a seed layer; a resist pattern forming unit configured to form, on the substrate, a resist pattern having an opening which surrounds the recess; a wiring layer forming unit configured to form a wiring layer within the recess by a plating process in which a plating liquid is supplied from the opening of the resist pattern; and an etching unit configured to remove the metal layer, among the metal layer on the substrate, layer located outside the wiring layer by an etching process. Here, the seed layer of the metal layer is formed by an electroless plating process.

In still another exemplary embodiment, there is provided a computer-readable recording medium having stored thereon computer-executable instructions that, in response to execution, cause a wiring layer forming system to perform a wiring layer forming method. Here, the wiring layer forming method includes preparing the substrate having a recess; forming, on a surface of the substrate and on an inner surface of the recess, a metal layer composed of a barrier layer and a seed layer; forming, on the metal layer, a resist pattern having an opening which surrounds the recess; forming a wiring layer within the recess by a plating process in which a plating liquid is supplied from the opening of the resist pattern; and removing the metal layer, among the metal layer on the substrate, located outside the wiring layer by an etching process. Further, the seed layer of the metal layer is formed by an electroless plating process.

According to the exemplary embodiments, the seed layer and the barrier layer located outside the wiring layer on the surface of the substrate can be easily and simply removed through an etching process after the wiring layer is formed within the recess of the substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a block diagram illustrating an overall wiring layer forming system according to an exemplary embodiment;

FIG. 2A to FIG. 2E are diagrams illustrating a substrate on which a wiring layer forming method is performed;

FIG. 3A to FIG. 3C are diagrams illustrating the substrate on which the wiring layer forming method is performed;

FIG. 4 is a side cross sectional view illustrating a barrier layer forming unit and a seed layer forming unit; and

FIG. 5 is a plan view illustrating the barrier layer forming unit and the seed layer forming unit.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein

<Wiring Layer Forming System>

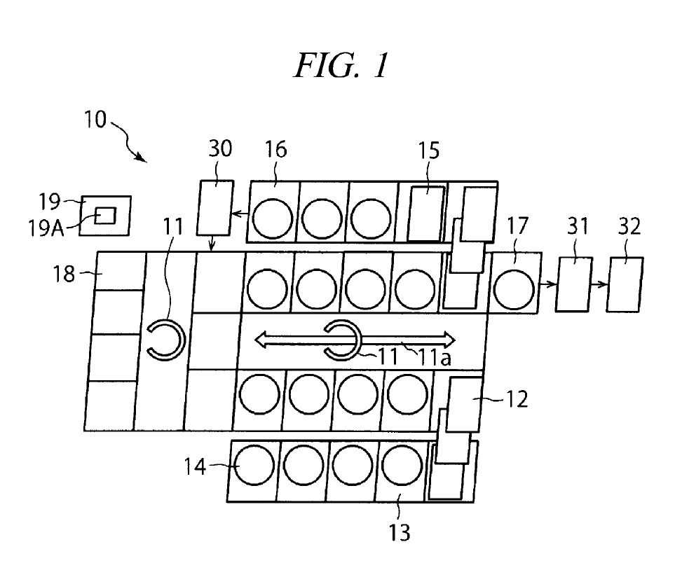

An exemplary embodiment will be described with reference to FIG. 1 to FIG. 5.

First, a wiring layer forming system in accordance with the exemplary embodiment will be elaborated with reference to FIG. 1.

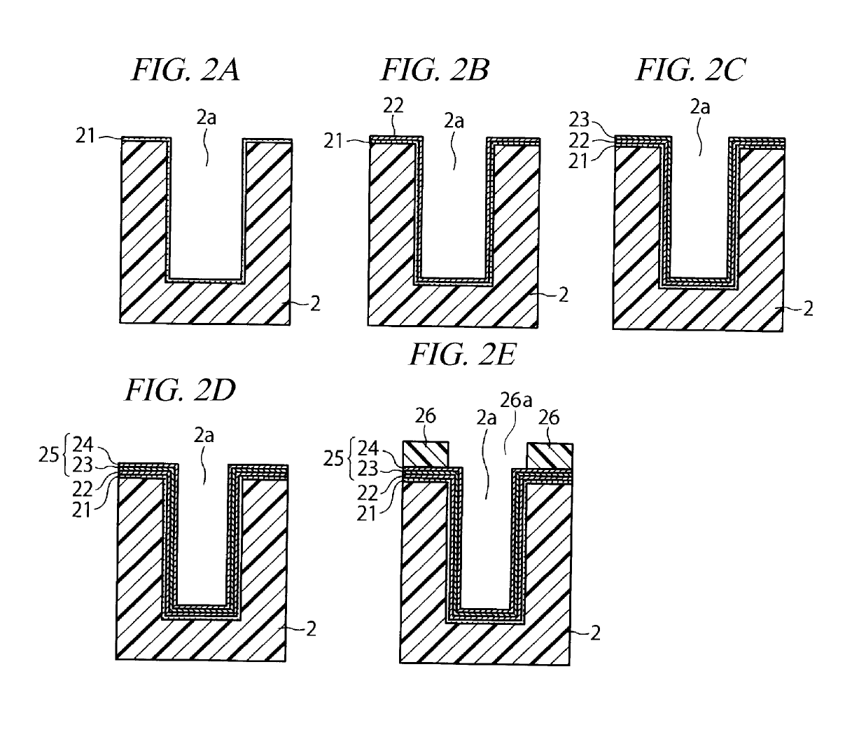

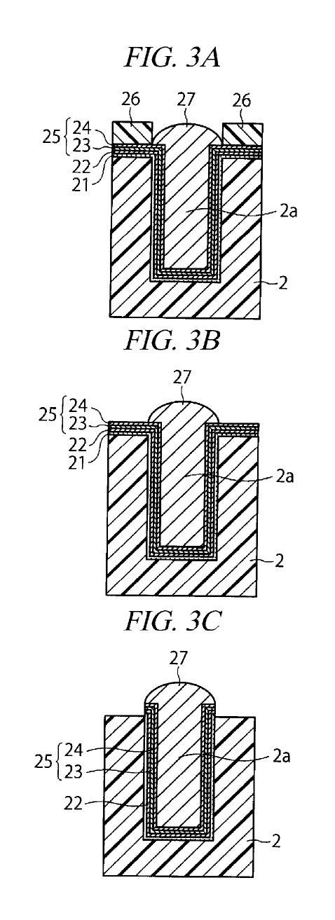

As depicted in FIG. 1, the wiring layer forming system 10 is configured to perform a plating process on a substrate (silicon substrate) 2, such as a semiconductor wafer, having a recess 2a (see FIG. 2A to FIG. 2E and FIG. 3A to FIG. 3C).

The wiring layer forming system 10 includes a cassette station 18 configured to mount thereon a cassette (not shown) which accommodates the substrate 2 therein; a substrate transfer arm 11 configured to take out the substrate 2 from the cassette on the cassette station 18 and transfer the substrate 2; and a moving path 11a along which the substrate transfer arm 11 is moved.

Further, arranged at one side of the moving path 11a are an adhesion layer forming unit 12 configured to form an adhesion layer 21 to be described later by adsorbing a coupling agent such as a silane coupling agent onto the substrate 2; a catalyst layer forming unit 13 configured to form a catalyst layer 22 to be described later by adsorbing a catalyst onto the adhesion layer 21 of the substrate 2; and a barrier layer forming unit 14 configured to form a barrier layer 23 serving as a Cu diffusion barrier film (barrier layer) to be described later on the catalyst layer 22 of the substrate 2.

Further, arranged at the other side of the moving path 11a are a baking unit 15 configured to bake the barrier layer 23 formed on the substrate 2; and a seed layer forming unit 16 configured to form an electroless copper plating layer (electroless Cu plating layer) serving as a seed layer 24 to be described later, on the barrier layer 23 formed on the substrate 2. Further, connected to the seed layer forming unit 16 is a resist pattern forming unit 30 configured to form, on the substrate 2, a resist pattern 26 having an opening 26a that surrounds the recess 2a.

Further, a wiring layer forming unit 17 configured to form a wiring layer 27 by filling the recess 2a of the substrate 2 with an electrolytic copper plating layer (electrolytic Cu plating layer) while using the electroless Cu plating layer 24 as a seed layer is provided adjacent to the baking unit 15.

Furthermore, a resist pattern removing unit 31 configured to remove the resist pattern 26 on the substrate 2 is connected to the wiring layer forming unit 17, and an etching unit 32 configured to remove, among the barrier layer 23 and the seed layer 24 on the substrate 2, the barrier layer 23 and the seed layer 24 located outside the wiring layer 27 by an etching process is connected to the resist pattern removing unit 31.

Here, both the barrier layer 23 formed by the barrier layer forming unit 14 and the seed layer 24 formed by the seed layer forming unit 16 are formed by an electroless plating process, as will be described later. The barrier layer 23 and the seed layer 24 constitute a metal layer 25.

In this regard, the barrier layer forming unit 14 and the seed layer forming unit 16 constitute a metal layer forming unit configured to form the metal layer 25.

Further, the resist pattern forming unit 30 is configured to form, on the substrate 2, the resist pattern 26 having the opening 26a that surrounds the recess 2a. Though not shown, the resist pattern forming unit 30 includes a resist coating unit configured to coat a resist on the substrate 2 on which the seed layer 24 is formed; a resist exposing unit configured to expose the resist to light; and a resist developing unit configured to develop the exposed resist.

Further, the respective constituent components of the above-described wiring layer forming system 10, for example, the cassette station 18, the substrate transfer arm 11, the adhesion layer forming unit 12, the catalyst layer forming unit 13, the barrier layer forming unit 14, the baking unit 15, the seed layer forming unit 16, the wiring layer forming unit 17, the resist pattern forming unit 30 and the etching unit 32 are controlled by a controller 19 according to various types of programs recorded in a recording medium 19A provided in the controller 19, so that various processes are performed on the substrate 2. Here, the recording medium 19A stores thereon various kinds of setup data or various kinds of programs such as a plating process program to be described later. The recording medium 19A may be implemented by a computer-readable memory such as a ROM or a RAM, or a disk-type recording medium such as a hard disk, a CD-ROM, a DVD-ROM or a flexible disk, as commonly known in the art.

Now, the barrier layer forming unit 14 configured to form the barrier layer 23 and the seed layer forming unit 16 configured to form the seed layer 24 will be further elaborated.

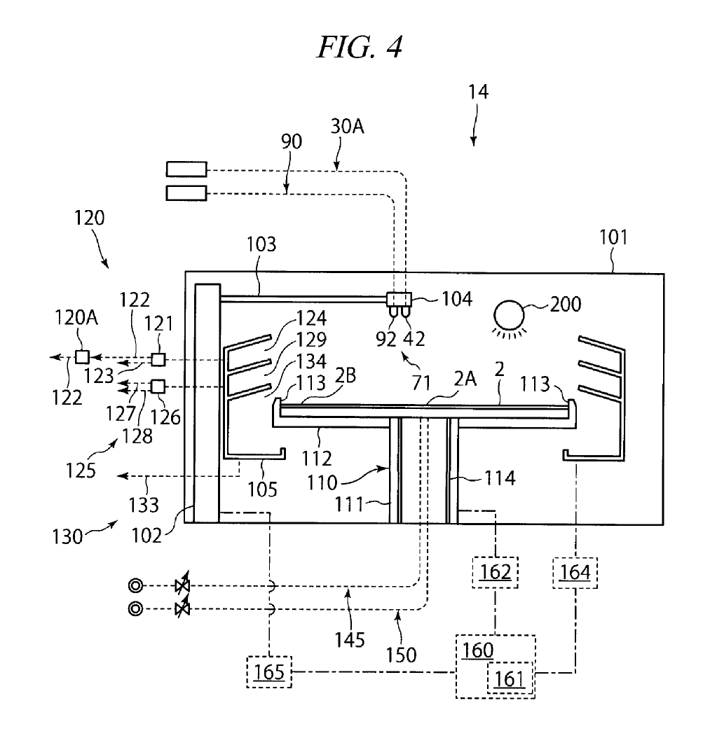

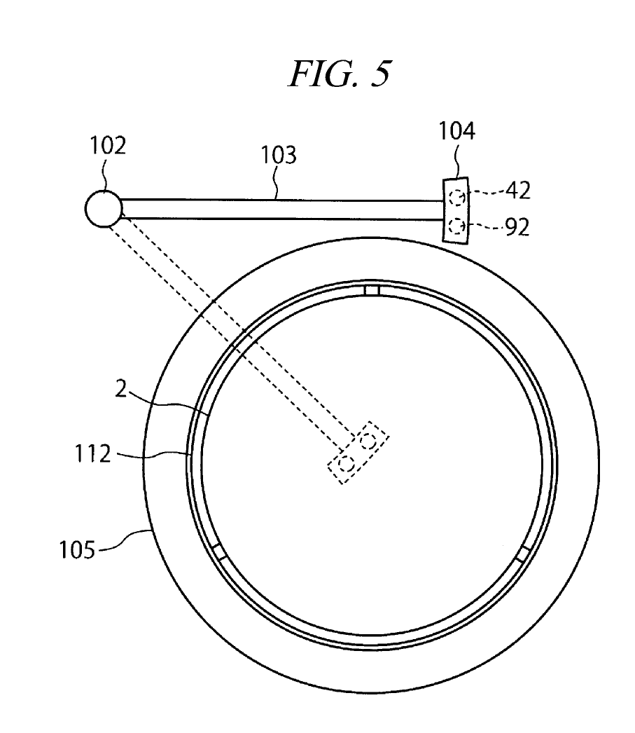

Each of the barrier layer forming unit 14 and the seed layer forming unit 16 may be implemented by a liquid processing apparatus as illustrated in FIG. 4 and FIG. 5.

Further, the barrier layer forming unit 14 and the seed layer forming unit 16 may be implemented by the same liquid processing unit. Accordingly, only the barrier layer forming unit 14 will be explained with reference to FIG. 4 and FIG. 5.

The barrier layer forming unit 14 includes, as shown in FIG. 4 and FIG. 5, a substrate holding/rotating device (substrate accommodating unit) 110 configured to hold and rotate the substrate 2 within a casing 101; liquid supplying devices 30A and 90 configured to supply a plating liquid, a cleaning liquid or the like onto a surface of the substrate 2; a recovery cup 105 configured to collect the plating liquid, the cleaning liquid or the like dispersed from the substrate 2; draining openings 124, 129 and 134 through which the plating liquid or the cleaning liquid collected by the recovery cup 105 are drained; liquid draining devices 120, 125 and 130 configured to drain the liquids collected in the draining openings; and a controller 160 for the barrier layer forming unit, configured to control the substrate holding/rotating device 110, the liquid supplying devices 30A and 90, the recovery cup 105 and the liquid draining devices 120, 125 and 130.

(Substrate Holding/Rotating Device)

The substrate holding/rotating device 110 includes, as illustrated in FIG. 4 and FIG. 5, a hollow cylindrical rotation shaft 111 vertically extended within the casing 101; a turntable 112 provided on an upper end portion of the rotation shaft 111; a wafer chuck 113 disposed on a peripheral portion of a top surface of the turntable 112 to support the substrate 2; and a rotating device 162 configured to rotate the rotation shaft 111. The rotating device 162 is controlled by the controller 160, and the rotation shaft 111 is rotated by the rotating device 162. As a result, the substrate 2 supported on the wafer chuck 113 is rotated.

Now, the liquid supplying devices 30A and 90 configured to supply a plating liquid, a cleaning liquid, or the like onto the surface of the substrate 2 will be explained with reference to FIG. 4 and FIG. 5. The liquid supplying device 30A is a plating liquid supplying device configured to supply a plating liquid onto the surface of the substrate 2. The liquid supplying device 90 is a cleaning liquid supplying device configured to supply a cleaning liquid onto the surface of the substrate 2.

As depicted in FIG. 4 and FIG. 5, a plating liquid discharge nozzle 42 is provided at a nozzle head 104. The nozzle head 104 is provided at a tip end portion of an arm 103. The arm 103 is provided at a supporting shaft 102 which is rotated by a rotating device 165 and can be extended in a vertical direction. A plating liquid supplying line of the plating liquid supplying device 30A is embedded within the arm 103. With this configuration, it is possible to discharge the plating liquid onto a target position on the surface of the substrate 2 through the plating liquid discharge nozzle 42 from a required supply height.

The cleaning liquid supplying device 90 is used to perform a cleaning process on the substrate 2 as will be described later. As illustrated in FIG. 4, the cleaning liquid supplying device 90 includes a nozzle 92 provided at the nozzle head 104.

In this configuration, either a cleaning liquid or a rinse processing liquid is selectively discharged onto the surface of the substrate 2 from the nozzle 92.

(Liquid Draining Device)

Now, the liquid draining devices 120, 125 and 130 configured to drain out the plating liquid or the cleaning liquid dispersed from the substrate 2 will be elaborated with reference to FIG. 4. As shown in FIG. 4, the recovery cup 105, which can be moved up and down by an elevating device 164 and has the draining openings 124, 129 and 134, is disposed within the casing 101. The liquid draining devices 120, 125 and 130 are configured to drain out the liquids collected in the draining openings 124, 129 and 134, respectively.

As depicted in FIG. 4, the liquid draining devices 120 and 125 include collecting flow paths 122 and 127 and waste flow paths 123 and 128, which are switched by flow path switching devices 121 and 126, respectively. Here, the plating liquid is collected and reused through the collecting flow paths 122 and 127, while the plating liquid is drained out through the waste flow paths 123 and 128. Further, as shown in FIG. 4, the processing liquid draining device 130 is only equipped with a waste flow path 133.

Further, as depicted in FIG. 4, a cooling buffer 120A configured to cool the plating liquid is provided at the collecting flow path 122.

<Method of Forming Wiring Layer>

An operation of the exemplary embodiment having the above-described configuration will be explained with reference to FIG. 2A to FIG. 3C.

First, in a pre-process, a recess 2a is formed on a substrate (silicon substrate) 2 such as a semiconductor wafer or the like. The substrate 2 having thereon the recess 2a is then transferred into the wiring layer forming system 10 according to the exemplary embodiment.

Within the adhesion layer forming unit 12 of the wiring layer forming system 10, an adhesion layer 21 is formed on the substrate 2 having the recess 2a (see FIG. 2A).

Here, as a method of forming the recess 2a on the substrate 2, a commonly known method in the art may be appropriately employed. Specifically, as a dry etching technique, for example, a general-purpose technique using a fluorine-based gas or a chlorine-based gas may be employed. Especially, in order to form a hole having a high aspect ratio (hole depth/hole diameter), a method using an ICP-RIE (Inductively Coupled Plasma Reactive Ion Etching) technique, which can perform a deep etching process with a high speed, may be more appropriately adopted. Especially, a Bosch process in which an etching process using sulfur hexafluoride (SF₆) and a protection process using a Teflon-based gas such as C₄F₈ are repeatedly performed may be appropriately utilized.

Further, the adhesion layer forming unit 12 has a decompression chamber (not shown) equipped with a heating unit. Within the adhesion layer forming unit 12, a coupling agent such as a silane coupling agent is adsorbed onto the substrate 2 having the recess 2a, so that the adhesion layer 21 is formed on the substrate 2 (SAM process). The adhesion layer 21 formed by adsorbing the silane coupling agent is configured to improve adhesivity between the substrate 2 and a catalyst layer 22 to be described later.

The substrate 2 on which the adhesion layer 21 is formed in the adhesion layer forming unit 12 is then transferred into the catalyst layer forming unit 13 by the substrate transfer arm 11. In the catalyst layer forming unit 13, a nano-palladium (n-Pd) serving as a catalyst is adsorbed on the adhesion layer 21 of the substrate 2, so that the catalyst layer 22 is formed (see FIG. 2B).

Now, the catalyst layer forming process in the catalyst layer forming unit 13 according to the exemplary embodiment will be further explained.

First, a catalyst solution supplied to the substrate 2 and a catalyst contained in the catalyst solution will be described.

As the catalyst adsorbed onto the adhesion layer 21 of the substrate 2, a catalyst having catalysis to accelerate a plating reaction may be appropriately used. By way of example, a catalyst formed of nanoparticles may be used. Here, the nanoparticle means a colloid particle that has catalysis and has an average particle diameter equal to or smaller than 20 nm, e.g., within the range from 0.5 nm to 20 nm. An element constituting the nanoparticles may include, by way of example, but not limitation, palladium, gold, platinum, or the like. Among these, the palladium of nanoparticle may be represented as n-Pd.

Further, as the element constituting the nanoparticles, ruthenium may be used.

A method of measuring the average particle diameter of the nanoparticles is not particularly limited, and various methods may be adopted. By way of example, when measuring the average particle diameter of the nanoparticles in the catalyst solution, a dynamic light scattering method may be employed. In the dynamic light scattering method, a laser beam is irradiated to the nanoparticles dispersed in the catalyst solution, and the average diameter of the nanoparticles is calculated by measuring scattered light.

Further, to measure the average particle diameter of the nanoparticles adsorbed on the recess 2a of the substrate 2, a preset number of nanoparticles, for example, twenty nanoparticles may be detected from an image which is obtained by using a TEM (Transmission Electron Microscope) or a SEM (Scanning Electron Microscope), and an average particle diameter of these nanoparticles may be calculated.

Now, the catalyst solution containing the catalyst formed of the nanoparticles will be elaborated. The catalyst solution contains ions of a metal constituting the nanoparticles serving as the catalyst. For example, if palladium constitutes the nanoparticles, the catalyst solution contains a palladium compound, such as palladium chloride, as a palladium ion source.

A specific composition of the catalyst solution is not particularly limited. Desirably, however, the composition of the catalyst solution is set such that the catalyst solution has a viscosity coefficient equal to or less than 0.01 Pa·s. By setting the viscosity coefficient of the catalyst solution to be in this range, the catalyst solution can be sufficiently diffused down to a bottom portion of the recess 2a of the substrate 2, even if a diameter of the recess 2a of the substrate 2 is small. Accordingly, the catalyst can be securely adsorbed to the bottom portion of the recess 2a of the substrate 2 as well more securely.

Desirably, the catalyst in the catalyst solution is coated with a dispersant. Accordingly, surface energy of the catalyst can be reduced. As a result, it is assumed that the diffusion of the catalyst within the catalyst solution can be more accelerated, so that the catalyst can reach the bottom portion of the recess 2a of the substrate 2 in a shorter time period.

Furthermore, it is assumed that an increase in the diameter of the catalyst caused by agglomeration of multiple catalysts can be suppressed, so that the diffusion of the catalyst in the catalyst solution can be further accelerated.

A method for preparing the catalyst coated with the dispersant is not particularly limited. By way of example, a catalyst solution containing the catalyst which is previously coated with the dispersant may be supplied to the catalyst layer forming unit 13. Alternatively, the catalyst layer forming unit 13 may be configured to perform therein a process of coating the catalyst with the dispersant.

Specifically, it is desirable to use polyvinylpyrrolidone (PVP), polyacrylic acid (PAA), polyethyleneimine (PEI), tetramethylammonium (TMA), citric acid, or the like as the dispersant.

Besides, various chemical materials for controlling characteristics thereof may be added into the catalyst solution.

Furthermore, the catalyst solution containing the catalyst may not be limited to the catalyst solution containing the nanoparticles such as n-Pd. By way of example, an aqueous solution of palladium chloride (PdCl₂) may be used as the catalyst solution, and Pd ions in the palladium chloride (PdCl₂) may be used as the catalyst.

After the catalyst layer 22 is formed on the substrate 2 in the catalyst layer forming unit 13 as stated above, the substrate 2 is then transferred into the barrier layer forming unit 14 by the substrate transfer arm 11.

Subsequently, in the barrier layer forming unit 14, a barrier layer 23 serving as a Cu diffusion barrier film (barrier film) is formed on the catalyst layer 22 of the substrate 2 (see FIG. 2C).

In this case, the barrier layer forming unit 14 is configured as the liquid processing apparatus as illustrated in FIG. 4 and FIG. 5. The barrier layer 23 can be formed by performing an electroless plating process on the catalyst layer 22 of the substrate 2.

When forming the barrier layer 23 in the barrier layer forming unit 14, a plating liquid containing, for example, Co—W—B may be used as a plating liquid, and a temperature of the plating liquid is maintained at 40° C. to 75° C. (desirably, 65° C.).

By supplying the plating liquid containing the Co—W—B onto the substrate 2, the barrier layer 23 containing the Co—W—B is formed on the catalyst layer 22 of the substrate 2 through the electroless plating process.

Thereafter, the substrate 2 having the barrier layer 23 formed on the catalyst layer 22 thereof is transferred from the barrier layer forming unit 14 into the baking unit 15 by the substrate transfer arm 11.

Within the baking unit 15, the substrate 2 is heated on a hot plate under an inert gas atmosphere where a N₂ gas is filled, in order to suppress the substrate 2 from being oxidized. Accordingly, the barrier layer 23 of the substrate 2 is baked (baking process).

When baking the barrier layer 23 in the baking unit 15, a baking temperature may be set to be in the range from, e.g., 150° C. to 200° C., and a baking time is set to be in the range from, e.g., 10 minutes to 30 minutes.

By baking the barrier layer 23 on the substrate 2 as described above, moisture within the barrier layer 23 can be removed, and, at the same time, the bond between metals within the barrier layer 23 can be enhanced.

The barrier layer 23 formed as described above serves as the Cu diffusion barrier layer (barrier film). The substrate 2 on which the barrier layer 23 is formed is then sent to the seed layer forming unit 16 by the substrate transfer arm 11.

Subsequently, in the seed layer forming unit 16, a seed layer 24 containing an electroless Cu plating layer serving as a seed film for forming a wiring layer 27 is formed on the barrier layer 23 of the substrate 2 (see FIG. 2D).

Here, the seed layer forming unit 16 is configured as the liquid processing apparatus as illustrated in FIG. 4 and FIG. 5. By performing the electroless plating process on the barrier layer 23 of the substrate 2, the seed layer 24 containing the electroless Cu plating layer can be formed.

The seed layer 24 containing the electroless Cu plating layer formed in the seed layer forming unit 16 serves as the seed film for forming the wiring layer 27. A plating liquid used in the seed layer forming unit 16 may contain a copper salt as a source of copper ions, such as copper sulfate, copper nitrate, copper chloride, copper bromide, copper oxide, copper hydroxide, copper pyrophosphate, or the like. The plating liquid may further contain a reducing agent and a complexing agent for the copper ions. Further, the plating liquid may further contain various kinds of additives for improving stability or speed of the plating reaction.

The barrier layer 23 and the seed layer 24 formed on the substrate 2 as described above constitute a metal layer 25, and the substrate 2 having the metal layer 25 formed thereon is sent into the resist pattern forming unit 30 from the seed layer forming unit 16.

Here, both the barrier layer 23 and the seed layer 24 of the metal layer 25 on the substrate 2 are formed by the electroless plating process. As compared to a case where the barrier layer 23 and the seed layer 24 are formed by, for example, a film forming process such as PVD or CVD, a thickness of the entire metal layer 25 can be reduced to 200 nm or less, e.g., 150 nm or less.

If the barrier layer 23 and the seed layer 24 are formed through the film forming process, the metal layer 25 may have a total thickness of 1000 nm or larger, and, in such a case, it may be difficult to remove the metal layer 25 through an etching process. According to the exemplary embodiment, however, the thickness of the entire metal layer 25 can be reduced, and, thus, the metal layer 25 can be removed easily by the etching process.

Further, the substrate 2 having the seed layer 24 thereon may be sent to the resist pattern forming unit 30 after sent to and baked in the baking unit 15.

In the resist pattern forming unit 30, a resist pattern 26 having an opening 26a which surrounds the recess 2a and is larger than the recess 2a is formed on the metal layer 25 of the substrate 2 (see FIG. 2E).

The substrate 2 having the resist pattern 26 formed on the metal layer 25 thereof as stated above is then sent to the wiring layer forming unit 17 by the substrate transfer arm 11. In the wiring layer forming unit 17, an electrolytic Cu plating process is performed on the substrate 2, so that an electrolytic Cu plating layer is filled within the recess 2a of the substrate 2 with the seed layer 24 as a seed film. This electrolytic plating layer serves the wiring layer 27 (see FIG. 3A).

Thereafter, the substrate 2 on which the wiring layer 27 is formed by filling the electrolytic Cu plating layer within the recess 2a is then sent to the resist pattern removing unit 31, and the resist pattern 26 on the substrate 2 is removed in this resist pattern removing unit 31 (see FIG. 3B).

In this case, the resist pattern 26 may be removed by dry etching or wet etching in the resist pattern removing unit 31.

Subsequently, the substrate 2 from which the resist pattern 26 is removed in the resist pattern removing unit 31 is sent to the etching unit 32. In the etching unit 32, the adhesion layer 21 and the metal layer 25 located outside the wiring layer 27 among the metal layer 25 on the substrate 2 are removed by the etching process (see FIG. 3C).

In the etching unit 32, the metal layer 25 can be easily removed with high accuracy by dry etching or wet etching.

That is, since the barrier layer 23 and the seed layer 24 of the metal layer 25 on the substrate 2 are both formed by the electroless plating process as described above, the thickness of the entire metal layer 25 on the surface of the substrate 2 is set to be equal to or less than 200 nm, desirably, equal to or less than 150 nm.

Therefore, the metal layer 25 can be easily and simply removed through the etching process in the etching unit 32.

In comparison, if both of the barrier layer 23 and the seed layer 24 of the metal layer 25 are formed by the film forming process such as PVD or CVD, the thickness of the metal layer 25 may be as large as 1000 nm or larger. Accordingly, when removing the metal layer 25 by the etching process, it takes a long time to complete the etching process, and even a part of the wiring layer 27 may be removed during this etching process.

According to the exemplary embodiment, however, since the metal layer 25 is formed by the plating process, the thickness of the entire metal layer 25 can be reduced, and, thus, the metal layer 25 can be removed by the etching process simply and easily.

Furthermore, since the metal layer 25 can be removed by the etching process in a very short time period, the wiring layer 27 is hardly etched during the etching process. In addition, since a high-priced film forming apparatus for PVD or CVD is not necessary to form the metal layer 25, the overall wiring forming system can be structured at low cost.

### Modification Examples of Exemplary Embodiment

Below, modification examples of the present exemplary embodiment will be described.

In the above-described exemplary embodiment, both the barrier layer 23 and the seed layer 24 of the metal layer 25 are formed by the electroless plating process. However, the exemplary embodiment is not limited thereto, and only the seed layer 24 may be formed by the electroless plating process while the barrier layer 23 is formed by the film forming process such as PVD or CVD.

Furthermore, in the exemplary embodiment, the barrier layer 23 containing the Co—W—B is formed by using the plating liquid containing Co—W—B. However, the exemplary embodiment is not limited thereto, and the barrier layer 23 may contain Ni or a Ni alloy instead. In addition, the barrier layer 23 may be formed in multiple layers made of a Ni alloy, a Co alloy, and the like.

Moreover, the exemplary embodiment has been described for the case where the wiring layer 27 contains the electrolytic Cu plating layer. However, the exemplary embodiment is not limited thereto, and the wiring layer 27 may contain an electrolytic Ni plating layer or an electrolytic Co plating layer. In case that the wiring layer 27 contains the electrolytic Ni plating layer, the seed layer 24 may contain Ni or a Ni alloy. Further, in case that the wiring layer 27 contains the electrolytic Co plating layer, the seed layer 24 may contain Co or a Co alloy. In these cases, the barrier layer 23 may not be formed.

Further, in the above-described exemplary embodiment, the substrate 2 is described to be provided with the recess 2a for forming the wiring layer 27. In addition to the recess 2a, however, the substrate 2 may further have an alignment mark (not shown) composed of a groove smaller than the recess 2a.

If the metal layer 25 including the barrier layer 23 and the seed layer 24 is formed on the substrate 2 by the film forming process, the thickness of the metal layer 25 may be increased, so that the alignment mark on the substrate 2 may be covered by the metal layer 25. In such a case, it is difficult to detect the alignment mark by a detector. According to the exemplary embodiment, however, since the metal layer 25 having a small thickness is formed on the substrate 2 through the plating process, the alignment mark is not covered by the metal layer 25.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting.

We claim:

1. A wiring layer forming method of forming a wiring layer on a substrate, comprising:
preparing the substrate having a recess;
forming, on a surface of the substrate and on an inner surface of the recess, a metal layer composed of a barrier layer and a seed layer;
forming, on the metal layer, a resist pattern having an opening which surrounds the recess;
forming a wiring layer within the recess by a plating process in which a plating liquid is supplied from the opening of the resist pattern; and
removing the metal layer, among the metal layer on the substrate, located outside the wiring layer by an etching process,
wherein the seed layer of the metal layer is formed by an electroless plating process.

2. The wiring layer forming method of claim 1,
wherein the barrier layer of the metal layer is formed by an electroless plating process.

3. The wiring layer forming method of claim 1,
wherein the barrier layer of the metal layer is formed by a film forming process including CVD or PVD.

4. The wiring layer forming method of claim 1,
wherein the metal layer has a thickness equal to or smaller than 200 nm.

5. The wiring layer forming method of claim 1,
wherein the barrier layer contains cobalt or a cobalt alloy.

6. The wiring layer forming method of claim 1,
wherein the seed layer contains copper or a copper alloy.

7. The wiring layer forming method of claim 1,
wherein the wiring layer is formed by an electrolytic plating process using the plating liquid containing copper.

8. A wiring layer forming system of forming a wiring layer on a substrate, comprising:
a metal layer forming unit configured to form, on a surface of the substrate having a recess and on an inner surface of the recess, a metal layer composed of a barrier layer and a seed layer;
a resist pattern forming unit configured to form, on the substrate, a resist pattern having an opening which surrounds the recess;
a wiring layer forming unit configured to form a wiring layer within the recess by a plating process in which a plating liquid is supplied from the opening of the resist pattern; and
an etching unit configured to remove the metal layer, among the metal layer on the substrate, layer located outside the wiring layer by an etching process,
wherein the seed layer of the metal layer is formed by an electroless plating process.

9. A computer-readable recording medium having stored thereon computer-executable instructions that, in response to execution, cause a wiring layer forming system to perform a wiring layer forming method,
wherein the wiring layer forming method comprises:
preparing the substrate having a recess;
forming, on a surface of the substrate and on an inner surface of the recess, a metal layer composed of a barrier layer and a seed layer;
forming, on the metal layer, a resist pattern having an opening which surrounds the recess;
forming a wiring layer within the recess by a plating process in which a plating liquid is supplied from the opening of the resist pattern; and
removing the metal layer, among the metal layer on the substrate, located outside the wiring layer by an etching process,
wherein the seed layer of the metal layer is formed by an electroless plating process.
